(19) United States
(12) Patent Application Publication
(10) Pub. No.: US 2026/0068554 A1
(43) Pub. Date: Mar. 5, 2026

(54) SELECTIVE DEPOSITION METHOD

(71) Applicant: ASM IP Holding B.V., Almere (NL)

(72) Inventors: Fatma Trabelsi, Leuven (BE); Werner Knaepen, Leuven (BE); Panagiota Arnou, Leuven (BE)

(21) Appl. No.: 19/311,827

(22) Filed: Aug. 27, 2025

Related U.S. Application Data
(60) Provisional application No. 63/688,066, filed on Aug. 28, 2024.

(51) Int. Cl. H01L 21/3205; C23C 16/04; C23C 16/30; C23C 16/40; C23C 16/455; H01L 21/768

(52) U.S. Cl. CPC H01L 21/32051; C23C 16/04; C23C 16/308; C23C 16/405; C23C 16/45531; C23C 16/45553

(57) ABSTRACT

A selective deposition method is disclosed. The selective deposition method comprises providing a plurality of substrates in a process chamber, the plurality of substrates having a first surface comprising a first material and a second surface comprising a second material, the first surface being different than the second surface, and selectively forming a layer comprising a metal on the first surface relative to the second surface, wherein selectively forming the layer comprises: i) contacting the plurality of substrates with a precursor comprising a compound of the form MXnOm, wherein: M is a metal; X is selected from the group consisting of F, Cl, Br, and I; n and m are integers; n+2m is at least 4 to at most 6; and ii) contacting the plurality of substrates with a reactant, wherein step i) comprises pulsing the precursor for a pulse duration of greater than 10 seconds.

### CROSS-REFERENCE TO RELATED APPLICATION(S)

This Application claims the benefit of U.S. Provisional Application 63/688,066 filed on Aug. 28, 2024, the entire contents of which are incorporated herein by reference.

### FIELD OF INVENTION

The present disclosure generally relates to a method to deposit material on a substrate. More particularly, the disclosure relates to selective deposition of material on a first surface of a substrate relative to a second surface.

### BACKGROUND OF THE DISCLOSURE

Integrated circuits are manufactured by an elaborate process in which various layers of materials are sequentially deposited in a predetermined arrangement on a semiconductor substrate. The predetermined arrangement of materials on a semiconductor substrate may often be accomplished by deposition of a material over the entire substrate surface, followed by removal of the material from predetermined areas of the substrate, such as for example by deposition of a mask layer and a subsequent etching process. The material may be conductive so as to provide for an electrical connection within the integrated circuit.

The number of steps involved in manufacturing an integrated surface on a substrate is very large making the production process very complex. The number of steps may be reduced by utilizing a selective deposition process, whereby a material is selectively deposited on a first surface relative to a second surface without the need, or with reduced need for subsequent processing.

The throughput of an integrated circuit manufacturing process may be improved by processing many substrates simultaneously in one reactor, for example a batch reactor or vertical furnace. However, processes used in single wafer reactors may not be simply translatable to batch reactors, due to the very different process conditions present, for example gas flow behaviour, temperature variation, quantity of precursor required, etc. Therefore, there is a need for selective deposition processes which are capable of being carried out on multiple substrates simultaneously.

### SUMMARY OF THE DISCLOSURE

According to a first embodiment of the present invention there is provided a selective deposition method comprising providing a plurality of substrates in a process chamber, the plurality of substrates having a first surface comprising a first material and a second surface comprising a second material, the first surface being different than the second surface; and selectively forming a layer comprising a metal on the first surface relative to the second surface, wherein selectively forming the layer comprises: i) contacting the plurality of substrates with a precursor comprising a compound of the form MXnOm, wherein: M is a metal; X is selected from the group consisting of F, Cl, Br, and I; n and m are integers; n+2m is at least 4 to at most 6; and ii) contacting the plurality of substrates with a reactant, wherein step i) comprises pulsing the precursor for a pulse duration of greater than 10 seconds.

Each substrate of the plurality of substrates may have a first surface and a second surface.

The metal comprised in the precursor may be one of a transition metal, a post transition metal, a rare earth metal. The metal comprised in the precursor may be molybdenum. The precursor may comprise a molybdenum oxychloride precursor. The molybdenum oxychloride precursor may comprise at least one of: molybdenum (V) trichloride oxide (MoOCl3), molybdenum (VI) tetrachloride oxide (MoOCl4), or molybdenum (IV) dichloride dioxide (MoO2Cl2).

Selectively forming the layer may comprise forming a first layer on the first surface and a second layer on the second surface which is at least twice as thick as the first layer.

Selectively forming the layer may comprise forming a first layer on the first surface and a second layer on the second surface which is at least five times as thick as the first layer.

Selectively forming the layer may comprise forming a first layer on the first surface and a second layer on the second surface which is at least ten times as thick as the first layer.

The reactant may comprise hydrogen. The reactant may comprise ammonia.

The method may comprise sequentially repeating steps i) and ii).

The method may comprise heating the substrate to a deposition temperature of more than 550° C. The method may comprise heating the substrate to a deposition temperature of more than 600° C.

The first material may be a metal. The first material may be a metal nitride. The first material may be a metal oxide.

The second material may be a dielectric material. The dielectric material may be silicon dioxide.

The pulse duration may be between 10 seconds and 30 seconds. The pulse duration may be greater than 30 seconds. The pulse duration may be greater than 2 minutes. The pulse duration may be greater than 4 minutes.

The precursor may have a partial pressure in the process chamber during step i) of at least 1 Torr. The precursor may have a partial pressure in the process chamber during step i) of at least 5 Torr. The precursor may have a partial pressure in the process chamber during step i) of at least 10 Torr.

The plurality of substrates may comprise a third surface comprising a third material which is different to the first and the second material, and selectively forming the layer may comprise selectively forming the layer on the first surfaces and on the third surfaces relative to the second surfaces.

The plurality of substrates may comprise a third surface comprising a third material which is different to the first and the second material, wherein selectively forming the layer comprises selectively forming the layer on the first surfaces relative to the second surfaces and the third surfaces.

The first material may be a metal or metal nitride, the second material may be a dielectric material, and the third material may be a metal oxide.

The method may further comprise depositing a seed layer by repeating steps i) and ii).

The reactant may comprise ammonia. The method may further comprise contacting the plurality of substrates with a hydrogen purge gas after at least one repetition of steps i) and ii).

The method may comprise, after depositing the seed layer, depositing a bulk layer of molybdenum on the seed layer.

According to a second aspect of the present invention there is provided a semiconductor processing apparatus comprising a process chamber for receiving a plurality of substrates supported on a substrate boat, at least one gas inlet for providing a gas to the process chamber, a gas exhaust for removing gas from the process chamber, a precursor gas supply, a reactant gas supply, and a controller configured to execute a set of instructions so as to carry out the steps of:
i) causing the plurality of substrates to be contacted with a precursor comprising a compound of the form MXnOm, wherein: M is a metal; X is selected from the group consisting of F, Cl, Br, and I; n and m are integers; n+2m is at least 4 to at most 6; and ii) causing the plurality of substrates to be contacted with a reactant, wherein step i) comprises pulsing the precursor for a pulse duration of greater than 10 seconds.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

Certain embodiments of the present invention will now be described, by way of example, with reference to the accompanying drawings, in which:

FIGS. 1a to 1d are schematic plan views of a substrate having first and second surfaces;

FIG. 1e is a schematic plan view of a substrate having first, second, and third surfaces;

FIG. 2a is a flowchart of a method according to embodiments of the present invention;

FIG. 2b is a flowchart of a further method according to embodiments of the present invention;

FIG. 3a is an X-ray diffraction spectrum of a silicon substrate coated with aluminum oxide after being subject to a selective deposition method according to embodiments of the present invention; no presence of molybdenum is detected. The X-ray diffraction spectrum of a silicon substrate coated with silicon dioxide after being subject to the same selective deposition method similarly showed no presence of molybdenum;

FIG. 3b is an X-ray diffraction spectrum of a silicon substrate coated with molybdenum nitride after being subject to a selective deposition method according to embodiments of the present invention; presence of molybdenum is detected;

FIG. 3c shows XPS analysis of a substrate coated with molybdenum nitride, after being subject to a selective deposition method according to embodiments of the present invention;

FIG. 4 is a schematic view of a substrate processing apparatus according to embodiments of the present invention.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below. The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

As used herein, the term “substrate” or “wafer” may refer to any underlying material or materials that may be used, or upon which, a device, a circuit, or a film may be formed. The term “semiconductor device structure” may refer to any portion of a processed, or partially processed, semiconductor structure that is, includes, or defines at least a portion of an active or passive component of a semiconductor device to be formed on or in a semiconductor substrate. Semiconductor substrates can be processed in batches in vertical furnaces. An example of such processing is the deposition of layers of various materials on the substrates.

Integrated circuits are manufactured by a process in which various layers of materials are sequentially deposited in a predetermined arrangement on a semiconductor substrate. A metal layer may be required as a conducting layer in a semiconductor device to electrically connect some of these layers. The number of steps involved in manufacturing an integrated surface on a substrate may be reduced by utilizing a selective deposition process, whereby a material is selectively deposited on a first surface relative to a second surface without the need, or with reduced need for subsequent processing. It has been found that there may be a need for a method of selectively depositing a conducting material on a first surface relative to a second surface to provide an electrical connection.

Gaps created during manufacturing of a feature of an integrated circuit device may be provided with metal material. The gaps may have a high aspect ratio in that their depth is much larger than their width. A gap may be provided through a series of layers of material, for example by etching. There may be a need to provide a conducting material in the gap. The gap may be more completely and uniformly filled by depositing material at the bottom of the gap and not on a side wall of the gap, to prevent formation of a seam.

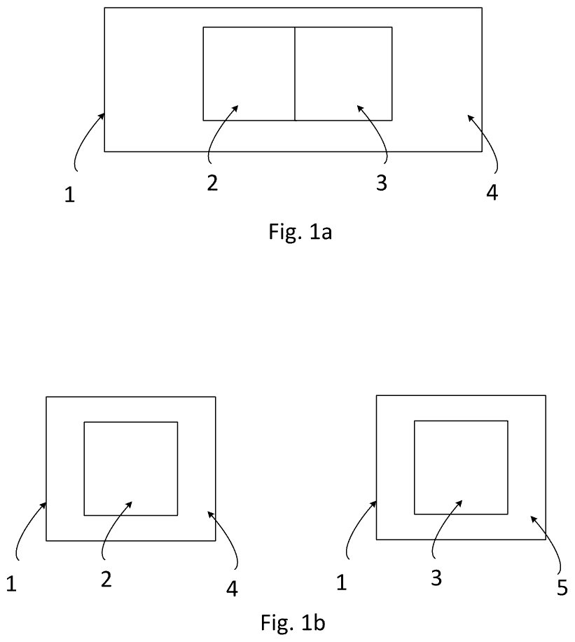

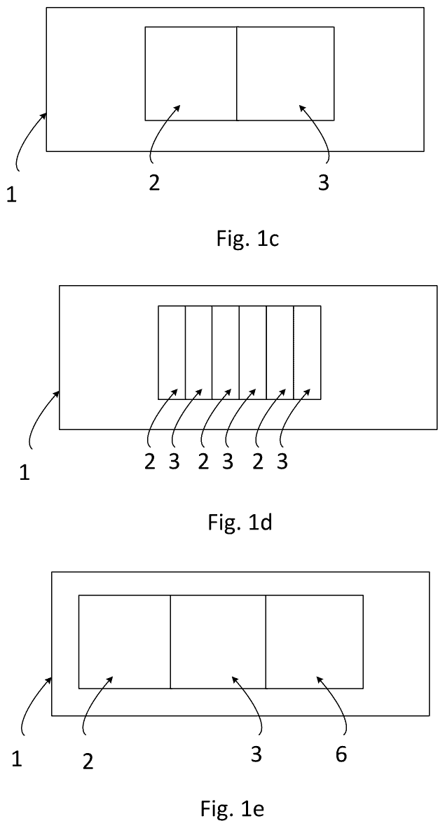

Referring to FIGS. 1a to 1d, a substrate 1 is shown having a first surface 2 and a second surface 3. The first surface 2 comprises a first material and the second surface 3 comprises a second material. The first material is different to the second material. The first surface 2 is different to the second surface 3, that is, the first surface 2 may not overlap with the second surface 3. The substrate 1 may have a first side 4 and a second, opposite side 5. Referring to FIG. 1a, the first surface 2 and the second surface 3 may both be provided on the first side 4 and/or the second side 5. The first surface 2 may be provided on the first side 4 and the second surface 3 may be provided on the second side 5 (FIG. 1b). The first surface 2 and the second surface 3 may be adjacent to each other (FIG. 1a) or spaced apart from each other (FIG. 1c). The first surface 2 and the second surface 3 may each be provided as a series of unconnected regions, for example the first surface 2 may be interspersed with the second surface 3 (FIG. 1d). It will be understood that various arrangements of the first and second surfaces 2, 3 relative to each other are possible within the scope of the present invention.

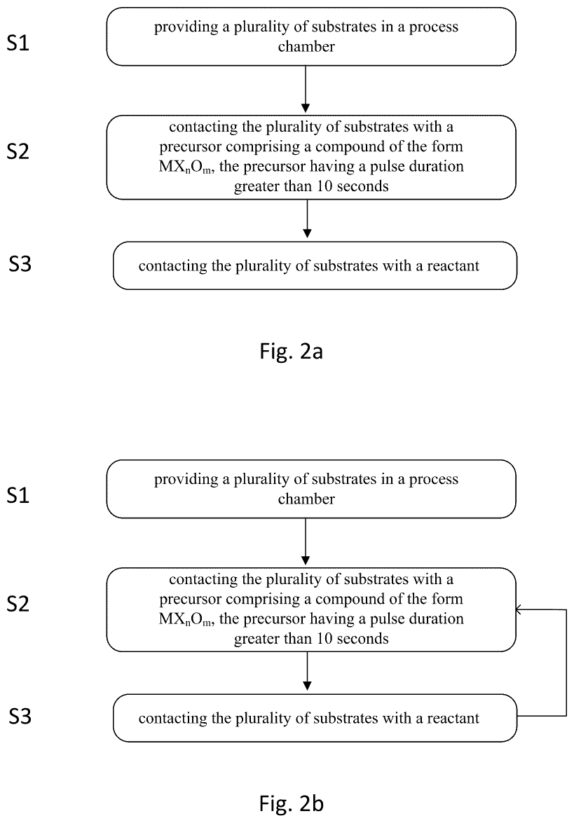

Referring to FIG. 2a, a method according to embodiments of the present invention may proceed as follows. In step S1, a plurality of substrates 1 is provided in a process chamber. The plurality of substrates has a first surface comprising a first material and a second surface comprising a second material, the first surface being different to the second surface. In step S2, the plurality of substrates are contacted with a precursor comprising a compound of the form MXnOm, wherein M is a metal; X is selected from the group consisting of F, Cl, Br, and I; n and m are integers; and n+2m is at least 4 to at most 6. O is oxygen. Step S2 comprises pulsing the precursor for a pulse duration of greater than 10 seconds. In step S3, the plurality of substrates 1 are contacted with a reactant. Steps S2 and S3 provide for selective formation of a layer comprising a metal on the first surfaces 2 relative to the second surfaces 3.

In step S1, providing the plurality of substrates in a process chamber may comprise providing a substrate carrier, or boat, supporting the plurality of substrates, in the process chamber. The process chamber is described in more detail hereinafter. The process chamber may be a process chamber of a batch reactor such as a vertical furnace. The plurality of substrates may comprise, for example, at least 50, at least 100, at least 150, at least 170 or more substrates. The plurality of substrates may have been subject to previous processing, for example deposition of multiple layers, etching, annealing, oxidation, and/or other processes to form structures on the plurality of substrates. The plurality of substrates may comprise semiconductor wafers, such as 200 mm or 300 mm or 450 mm wafers. The plurality of substrates has a first surface and a second surface. In some embodiments, each substrate 1 has a first surface 2 and a second surface 3. In some embodiments, the first surface is a surface of a first (set of) substrates in the plurality of substrates and the second surface is a surface of a second (set of) substrates in the plurality of substrates, the first (set of) substrates being different to the second (set of) substrates. Reference herein to selective deposition on a first surface relative to a second surface may refer to selective deposition on each first surface of each of the plurality of substrates relative to each second surface of the respective substrate in the plurality of substrates. Reference herein to selective deposition on a first surface relative to a second surface may refer to selective deposition on a first surface of the first (set of) substrates relative to a second surface of the second (set of) substrates in the plurality of substrates.

Referring to FIG. 2b, the selective deposition process of steps S2 and S3 may be repeated sequentially until the layer comprising the metal formed on the first surfaces has a desired thickness, for example the selective deposition process of steps S2 and S3 may be an atomic layer deposition process. In between steps S2 and S3 the process chamber may be purged with a purge gas. After step S3 the process chamber may be purged with a purge gas. The purge gas may be an inert gas such as argon or helium. The purge gas may be provided to the chamber for a duration of between 30 seconds and 60 seconds. Other purge gas provision durations are possible.

The precursor in step S2 is provided as a pulse of duration T1 which is greater than 10 seconds. For example, in some embodiments T1 may be at least 10 seconds, at least 20 seconds, at least 30 seconds. In some embodiments, T1 may be between 10 seconds and 30 seconds, between 30 seconds and one minute, between one minute and two minutes, between two minutes and three minutes, or between three minutes and four minutes. In some embodiments, T1 may be greater than one minute, for example between one minute and two minutes, or between one minute and three minutes, or between one minute and four minutes. In some embodiments, T1 may be greater than two minutes, for example between two minutes and three minutes, or between two minutes and four minutes. In some embodiments, T1 may be greater than four minutes, for example between four minutes and five minutes, between four minutes and six minutes, between four minutes and seven minutes, between four minutes and eight minutes. The reactant in step S3 may be provided as a pulse of duration T2 which may be between 30 seconds and 60 seconds. Other values of T2 are possible, for example less than 30 seconds or greater than 60 seconds.

The precursor comprises a compound of the form MXnOm. M is a metal, for example a transition metal, a post transition metal, a rare earth metal. The transition metal may be selected from the group of Molybdenum (Mo), Tungsten (W), Ruthenium (Ru), Cobalt (Co), and Copper (Cu). In some embodiments, the metal is chosen to be molybdenum and the precursor comprises a molybdenum oxyhalide.

X is selected from the group consisting of F, Cl, Br, and I, that is, the halogens excluding astatine and tennessine. In some embodiments, the metal is molybdenum and X is a chloride, thus forming a molybdenum oxychloride precursor. The precursor may comprise molybdenum (V) trichloride oxide (MoOCl3), molybdenum (VI) tetrachloride oxide (MoOCl4), or molybdenum (IV) dichloride dioxide (MoO2Cl2).

The reactant may comprise hydrogen, for example hydrogen gas (H2). The reactant may comprise ammonia (NH3).

The first material may comprise a metal, e.g. a transition metal. The transition metal may be selected from the group of molybdenum, titanium (Ti), tantalum (Ta), manganese (Mn), tungsten (W), Ruthenium (Ru), Cobalt (Co), and Copper (Cu). The first material may comprise a metal nitride. The first material may comprise a metal oxide.

The second material is different to the first material. The second material may comprise an oxide, nitride or combination thereof. The oxide, nitride or combination thereof may be selected from the group of aluminum oxide (AlOx), silicon oxide (SiOx), silicon nitride (SiN), hafnium oxide (HfO2), zirconium oxide (ZrO2) and silicon oxynitride (SiON). The silicon oxide may be a thermal oxide of silicon. The silicon oxide may be carbon doped. The second material may be a dielectric material.

For example, in some embodiments, the first material may be aluminum oxide and the second material may be silicon dioxide. In some embodiments, the first material may be molybdenum or molybdenum nitride and the second material may be aluminum oxide. In some embodiments, the first material may be molybdenum or molybdenum nitride and the second material may be silicon dioxide.

Selectively forming the layer comprising a metal on the first surfaces relative to the second surfaces may comprise forming a thicker layer comprising a metal on the first surfaces than on the second surfaces. For example, a first layer comprising the metal may be formed on the first surfaces and a second layer comprising the metal may be formed on the second surfaces, and the first layer may have a thickness which is at least two times a thickness of the second layer. Thus, the first layer is selectively deposited relative to the second layer, because the first layer is substantially thicker than the second layer. The first layer may be five or ten times as thick as the second layer. The first layer may be twenty times as thick as the second layer. In some embodiments, no layer or no detectable layer is deposited on the second surfaces. In some embodiments, the second layer has a thickness which is less than 5 angstroms, less than 2 angstroms, or less than 1 angstrom.

In steps S2 and S3, the plurality of substrates may be heated to a temperature of at least 550 C. The heating may be provided by a process chamber heater. The plurality of substrates may be heated to a temperature of at least 600 C. The plurality of substrates may be heated to a temperature of at least 550 C and less than 650 C. The plurality of substrates may be heater to a temperature of at least 600 C and less than 700 C.

In step S2, the partial pressure of the precursor in the process chamber may be controlled to have a value which is at least 1 Torr. In some embodiments, the partial pressure may be at least 5 Torr or at least 10 Torr. In some embodiments, the partial pressure may be between 1 Torr and 10 Torr, for example between 1 Torr and 2 Torr, be between 1 Torr and 2 Torr, between 2 Torr and 3 Torr, between 3 Torr and 4 Torr, between 4 Torr and 5 Torr, between 5 Torr and 6 Torr, between 6 Torr and 7 Torr, between 7 Torr and 8 Torr, between 8 Torr and 9 Torr, between 9 Torr and 10 Torr. In some embodiments, the partial pressure may be greater than 10 Torr, for example between 10 Torr and 11 Torr, between 11 Torr and 12 Torr, between 12 Torr and 13 Torr, between 13 Torr and 14 Torr, or between 14 Torr and 15 Torr. In some embodiments, the partial pressure may be between 0.5 Torr and 1 Torr, for example between 0.5 Torr and 0.6 Torr, between 0.6 Torr and 0.7 Torr, between 0.7 Torr and 0.8 Torr, between 0.8 Torr and 0.9 Torr, between 0.9 Torr and 1 Torr. The partial pressure may be chosen in dependence on the selectivity required. In some embodiments, a small quantity of inert gas such as argon may be co-flowed with the precursor, which may help to prevent backflow diffusion of the precursor into gas lines upstream of the process chamber. For example, a gas provided to the process chamber in step S2 may comprise 90% precursor and 10% argon (or other inert gas), or 95% precursor and 5% argon (or other inert gas).

Referring to FIG. 1e, in some embodiments, the plurality of substrates 1 comprises a third surface 6 comprising a third material which is different to the first and the second material. In some embodiments, the third surface 6 may be comprised in each of the plurality of substrates 1. In some embodiments, the third surface 6 may be comprised in a third (set of) substrates which is different to a first (set of) substrates comprising the first surface and a second (set of) substrates comprising the second surface. The third surface 6 may be different to the first surface 2 and the second surface 3, that is, the first surface 6 may not overlap with the first surface 2 and the second surface 3. The first surface 2 and the third surface 6 may be provided on the first side 4 of the substrate 1 and the second surface 3 may be provided on the second side 5 of the substrate 1. The first surface 2 and the second surface 3 may be provided on the first side 4 of the substrate 1 and the third surface 6 may be provided on the second side 5 of the substrate 1. The second surface 3 and the third surface 6 may be provided on the first side 4 and the first surface 2 may be provided in the second side 5. The first surface 2, the second surface 3, and the third surface 10 may each be provided on the first side 4 and/or the second side 5. The first, second and third surfaces 2, 3, 6 may be adjacent to each other or spaced apart from each other. The first, second, and third surfaces 2, 3, 6 may each be provided as a series of unconnected regions, for example one or more of the surfaces 2, 3, 6 may be interspersed with one or more of the surfaces 2, 3, 6. It will be understood that various arrangements of the first and second surfaces 2, 3, 6 relative to each other are possible within the scope of the present invention.

The third material may be a metal oxide, for example aluminum oxide or hafnium dioxide. The third material may be a metal nitride, for example titanium nitride or vanadium nitride.

In some embodiments, the method comprises selectively forming the layer comprising a metal on the first surfaces 2 and the third surfaces 10 relative to the second surfaces 3. Selectively forming the layer comprising a metal on the first surfaces 2 and the third surfaces 10 relative to the second surfaces 3 may comprise forming a thicker layer on the first surfaces 2 and the third surfaces 10 than on the second surfaces 3. For example, a first layer comprising the metal may be formed on the first surfaces and a second layer comprising the metal may be formed on the second surfaces and a third layer comprising the metal may be formed on the third surfaces. The first layer may have a thickness which is at least two times a thickness of the second layer. The third layer may have a thickness which is at least two times a thickness of the second layer. Thus, the first layer and the third layer are selectively deposited relative to the second layer, because the first layer and the third layer are substantially thicker than the second layer. The first layer may be five or ten times as thick as the second layer. The third layer may be five or ten times as thick as the second layer. The first layer may be twenty times as thick as the second layer. The third layer may be twenty times as thick as the second layer. The first layer and the third layer do not necessarily have the same thickness. In some embodiments, no layer or no detectable layer is deposited on the second surfaces. In some embodiments, the second layer has a thickness which is less than 5 angstroms, less than 2 angstroms, or less than 1 angstrom.

In some embodiments, the method comprises selectively forming the layer comprising a metal on the first surfaces 2 relative to the second surfaces 3 and the third surfaces 10. Selectively forming the layer comprising a metal on the first surfaces 2 relative to the second surfaces 3 and the third surfaces 10 may comprise forming a thicker layer on the first surfaces 2 than on the second surfaces 3 and the third surfaces 10. For example, a first layer comprising the metal may be formed on the first surfaces and a second layer comprising the metal may be formed on the second surfaces and a third layer comprising the metal may be formed on the third surfaces. The first layer may have a thickness which is at least two times a thickness of the second layer. The first layer may have a thickness which is at least two times a thickness of the third layer. Thus, the first layer is selectively deposited relative to the second layer and the third layer, because the first layer is substantially thicker than the second layer and the third layer. The first layer may be five or ten times as thick as the second layer. The first layer may be five or ten times as thick as the third layer. The first layer may be twenty times as thick as the second layer. The first layer may be twenty times as thick as the third layer. The second layer and the third layer do not necessarily have the same thickness. In some embodiments, no layer or no detectable layer is deposited on the second surfaces. In some embodiments, the second layer has a thickness which is less than 5 angstroms, less than 2 angstroms, or less than 1 angstrom. In some embodiments, no layer or no detectable layer is deposited on the third surfaces. In some embodiments, the third layer has a thickness which is less than 5 angstroms, less than 2 angstroms, or less than 1 angstrom.

In some embodiments, the layer comprising a metal may be a molybdenum layer. In some embodiments, the layer comprising a metal may be a layer of molybdenum nitride. In some embodiments, the layer comprising a metal may be a layer of molybdenum oxynitride.

In some embodiments, the first material may be a metal or metal nitride, the second material may be a dielectric material, and the third material may be a metal oxide. For example, the first material may be molybdenum nitride and the second material may be silicon dioxide and the third material may be aluminum oxide. Thus, methods according to embodiments of the present invention may provide for selective deposition on a first surface comprising a metal nitride, e.g. molybdenum nitride, relative to a second surface comprising a dielectric, e.g. silicon dioxide, and to a third surface comprising a metal oxide, e.g. aluminum oxide. Methods according to embodiments of the present invention may provide for selective deposition on a first surface comprising a metal nitride, e.g. molybdenum nitride, and on a third surface comprising a metal oxide, e.g. aluminum oxide, relative to a second surface comprising a dielectric, e.g. silicon dioxide.

In some embodiments, the precursor comprises molybdenum oxychloride and the reactant comprises ammonia. The selectively deposited layer comprising a metal is then molybdenum oxynitride MoON. The MoON layer may be left as MoON or may be converted to MoN by contacting the plurality of substrates with hydrogen after at least one repetition of steps S2 and S3. In some embodiments, the first material may be aluminum oxide, the second material may be silicon dioxide, and MoON may be selectively deposited on aluminium oxide and not on silicon dioxide.

In some embodiments, a thin seed layer of MoON may be selectively deposited on the aluminum oxide. Subsequently, a bulk layer of molybdenum may be selectively deposited on the seed layer, for example using a method according to embodiments of the present invention. The deposition process for the bulk layer may comprise repeating steps S2 and S3 M times, with M selected between 5 and 2000, preferably 100 and 500, and more preferably 300 and 400. The bulk layer may have a thickness between 1 nm and 700 nm, preferably 5 nm and 500 nm, more preferably between 50 nm and 300 nm on the first surface of the substrate. Optionally, a purge step of contacting the plurality of substrates with hydrogen may be carried out before depositing the bulk layer of molybdenum, so as to reduce the oxygen content of the MoON layer. Use of the MoON seed layer may be especially beneficial in applications wherein deposition of molybdenum on aluminum oxide (or other material) is challenging.

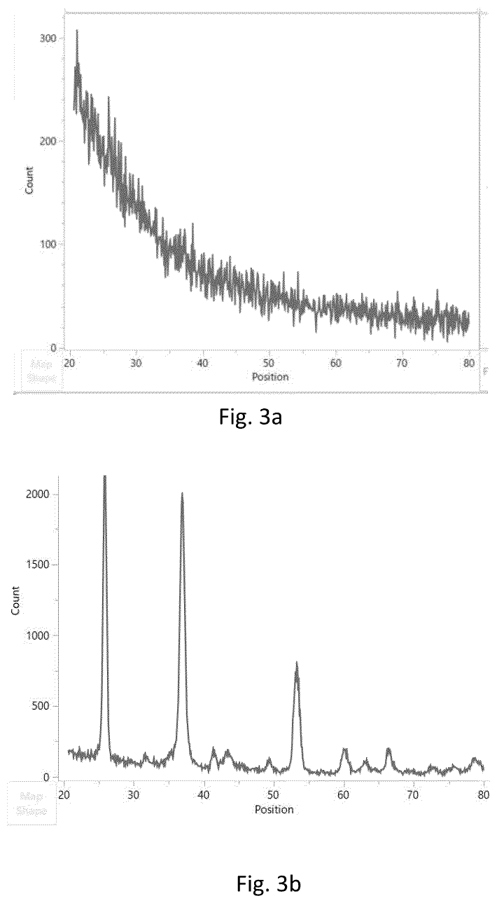

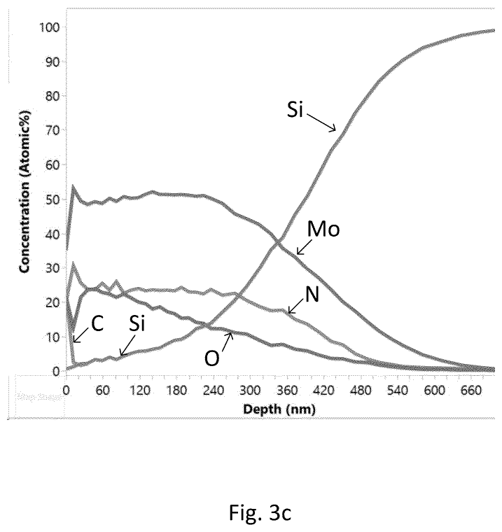

A selective deposition process according to embodiments of the present invention was carried out in a SONORA® vertical batch furnace (available from ASM International N.V., Netherlands). Substrates including a silicon substrate coated with aluminum oxide, a silicon substrate coated with silicon dioxide, and a silicon substrate coated with molybdenum nitride were provided in the process chamber of the vertical furnace. The precursor was molybdenum dichloride dioxide and the reactant was ammonia. The precursor pulse duration was 4 minutes, with a precursor partial pressure of 10 Torr. At a substrate temperature of 600 C, the precursor and reactant were alternately provided to the process chamber 150 times. X-ray photoelectron spectroscopy analysis was carried out on each substrate. X-ray diffraction (XRD) analysis was carried out on each substrate. No detectable amount of molybdenum was found on either of the substrates coated with aluminum oxide or silicon dioxide in the X-ray diffraction analysis (FIG. 3a), whereas clear MoO₂+Mo₂N diffraction peaks are seen for the molybdenum nitride coated substrate (FIG. 3b). The XPS analysis shown in FIG. 3c of the metal-coated substrate shows that a 270 nm layer of Mo₂OₓN_{y} was deposited.

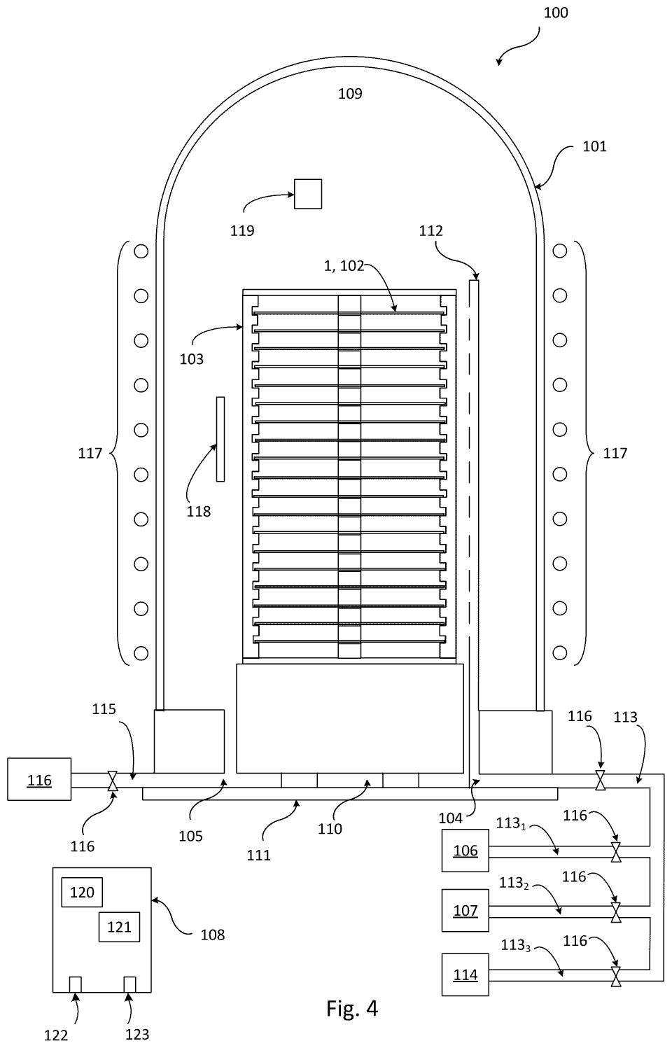

Referring to FIG. 4, a semiconductor processing apparatus 100 according to embodiments of the present invention is shown, in which a method of selective deposition as described herein may be carried out. The apparatus comprises a process chamber 101 for receiving a plurality of substrates 1, 102 supported on a substrate carrier or boat 103, at least one gas inlet 104 through which a gas may be provided to the process chamber 101, a gas exhaust outlet 105 through which a gas may be removed from the process chamber 101, a precursor gas supply 106, a reactant gas supply 107, and a controller 108.

The process chamber 101 may be generally bell jar shaped and may extend in a longitudinal direction, which may be aligned horizontally or vertically. The process chamber 101 may have has an open end 109 and a closed end 110. The substrate carrier 103 may be inserted into the process chamber 101 through the open end 109. The open end 109 may be closed off by a door 111.

The apparatus 100 may comprise one or more gas injectors 112 connected to the gas inlet 104 for providing one or more gases to the interior of the process chamber 101. The one or more gas injectors 112 may be dump injectors, multi hole injectors, or other injector types. The gas inlet 104 may be connected one or more gas lines 113 for supplying gas to the process chamber 101. The one or more gas lines 113 may include a first gas line 113₁ for providing a precursor gas from the precursor gas supply 106, a second gas line 113₂ for providing a reactant gas from the reactant gas supply 107, and a third gas line 113₄ for providing a purge gas from a purge gas supply 114. One or more of the precursor gas supply 106, the reactant gas supply 107, and the purge gas supply 114 may be connected to respective sub-fab sources (not shown). The apparatus 1 may comprise one or more gas exhaust lines 115 connected to the gas outlet 105 for removing gases from the interior of the process chamber 101. The gas exhaust line 115 may be connected to a vacuum pump 116. One or more flow controllers 116 may be provided in the gas lines 113, 115 so as to control flow rate of gas into/out of the process chamber 101 and consequently the pressure in the process chamber 101. The flow controllers 116 may comprise, for example, one or more of a valve, a mass flow controller, a pressure control valve.

The apparatus 100 may comprise heating elements 117 for heating the process chamber 101. The apparatus 100 may comprise one or more temperature sensors 118, for example thermocouples, in the process chamber 101 for measuring a temperature in the process chamber 101. The apparatus 100 may comprise one or more pressure sensors 119 in the process chamber 101 for measuring a process chamber pressure. The controller 108 may be configured to control, for example, the heating elements 117 (thereby controlling the temperature of the substrates 102 in the process chamber 101) and the valves/mass flow controllers 116 (thereby controlling the type(s) of gas(es) provided to the process chamber 101 and the pressure thereof and the time for which the gas(es) are provided).

The controller 108 may be implemented in hardware or in software. The controller 108 may be (physically) part of a central control module (not shown) or may be (physically) separate from and in communication with a central control module (not shown). The controller 108 may comprise a memory 120 configured to store instructions for performing a method according to embodiments of the present invention. The controller 108 may comprise a processor 121 which may be configured for processing and carrying out instructions loaded from the memory 120. The controller 108 may comprise one or more inputs 122 for receiving data, signals, and/or instructions from elements comprised in the substrate processing apparatus 100, for example measurements of pressure, temperature, ozone concentration, etc. from pressure sensors, temperature sensors, ozone concentration sensors, etc. The controller 108 may comprise one or more outputs 123 for providing data, signals, and/or instructions to elements comprised in the substrate processing apparatus 100, for example flow controllers 116, heaters 117, in order to control, for example, process chamber pressure, precursor/reactant/purge gas pule duration, and process chamber temperature.

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims.

The methods according to embodiments of the present invention are not limited to application in a vertical furnace or batch processing apparatus and can equally be implemented in a single wafer or minibatch reactor.

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, it is noted that particular features, structures, or characteristics of one or more embodiments may be combined in any suitable manner to form new, not explicitly described embodiments. The subject matter of the present disclosure includes all novel and nonobvious combinations and subcombinations of the various processes, systems, and configurations, and other features, functions, acts, and/or properties disclosed herein, as well as any and all equivalents thereof.

1. A selective deposition method comprising:
providing a plurality of substrates in a process chamber, the plurality of substrates having a first surface comprising a first material and a second surface comprising a second material, the first surface being different than the second surface, and
selectively forming a layer comprising a metal on the first surface relative to the second surface,
wherein selectively forming the layer comprises:
i) contacting the plurality of substrates with a precursor comprising a compound of the form MXₙOₘ, wherein:
M is a metal;
X is selected from the group consisting of F, Cl, Br, and I;
n and m are integers;
n+2m is at least 4 to at most 6; and
ii) contacting the plurality of substrates with a reactant,
wherein step i) comprises pulsing the precursor for a pulse duration of greater than 10 seconds.

2. A method according to claim 1, wherein each substrate of the plurality of substrates has a first surface and a second surface.

3. A method according to claim 1, wherein the metal comprised in the precursor is one of a transition metal, a post transition metal, a rare earth metal.

4. A method according to claim 1, wherein the metal comprised in the precursor is molybdenum.

5. A method according to claim 3, wherein the precursor comprises a molybdenum oxychloride precursor, wherein the molybdenum oxychloride precursor comprises at least one of: molybdenum (V) trichloride oxide (MoOCl3), molybdenum (VI) tetrachloride oxide (MoOCl4), or molybdenum (IV) dichloride dioxide (MoO2Cl2).

6. A method according to claim 1, wherein selectively forming the layer comprises forming a first layer on the first surface and a second layer on the second surface, wherein the second layer is at least twice as thick as the first layer.

7. A method according to claim 1, wherein the reactant comprises hydrogen.

8. A method according to claim 1, wherein the reactant comprises ammonia.

9. A method according to claim 1, comprising sequentially repeating steps i) and ii).

10. A method according to claim 1, further comprising heating the plurality of substrates to a deposition temperature of more than 550° C.

11. A method according to claim 1, wherein the first material is a metal.

12. A method according to claim 1, wherein the first material is a metal nitride.

13. A method according to claim 1, wherein the first material is a metal oxide.

14. A method according to claim 1, wherein the second material is silicon dioxide.

15. A method according to claim 1, wherein the pulse duration is between 10 second and 30 seconds.

16. A method according to claim 1, wherein the pulse duration is greater than 30 seconds.

17. A method according to claim 1, wherein the precursor has a partial pressure in the process chamber during step i) of at least 5 Torr.

18. A method according to claim 1, wherein the precursor has a partial pressure in the process chamber during step i) of at least 10 Torr.

19. A method according to claim 1, further comprising depositing a seed layer by repeating steps i) and ii).

20. A semiconductor processing apparatus comprising a process chamber for receiving a plurality of substrates supported on a substrate boat, at least one gas inlet for providing a gas to the process chamber, a gas exhaust for removing gas from the process chamber, a precursor gas supply, a reactant gas supply, and a controller configured to execute a set of instructions so as to carry out the steps of:
i) causing the plurality of substrates to be contacted with a precursor comprising a compound of the form MXₙOₘ, wherein:
M is a metal;
X is selected from the group consisting of F, Cl, Br, and I;
n and m are integers;
n+2m is at least 4 to at most 6; and
ii) causing the plurality of substrates to be contacted with a reactant, wherein step i) comprises pulsing the precursor for a pulse duration of greater than 10 seconds.
